(19) United States
(12) Patent Application Publication
(10) Pub. No.: US 2025/0246901 A1
(43) Pub. Date: Jul. 31, 2025

(54) PROTECTION CIRCUIT AND SEMICONDUCTOR DEVICE

(71) Applicant: ABLIC Inc., Nagano (JP)

(72) Inventor: Tsutomu TOMIOKA, Nagano (JP)

(73) Assignee: ABLIC Inc., Nagano (JP)

(21) Appl. No.: 19/023,394

(22) Filed: Jan. 16, 2025

(30) Foreign Application Priority Data
Jan. 31, 2024 (JP) 2024-012793

(51) Int. Cl. H02H 9/02

(52) U.S. Cl. CPC H02H 9/025

(57) ABSTRACT

A protection circuit includes: an NMOS transistor, including a first end (source), a second end (drain), and a control end (gate), the first end being connected with a first end of a current path formed by parasitic diodes of a semiconductor element included in an internal circuit, and the second end being connected with a GND terminal; and a current limiting circuit, connected in parallel with the NMOS transistor.

### CROSS-REFERENCE TO RELATED APPLICATION

This application claims the priority benefit of Japan application serial no. 2024-012793, filed on Jan. 31, 2024. The entirety of the above-mentioned patent application is hereby incorporated by reference herein and made a part of this specification.

### BACKGROUND

### Technical Field

The present invention relates to a protection circuit and a semiconductor device.

### Description of Related Art

A power supply device (for example, a secondary battery, etc.) that supplies power to a semiconductor device may apply a power supply voltage with a polarity (hereinafter simply referred to as “reverse polarity”) opposite to the polarity applied in a steady state due to reverse connection of a connector or noise, etc. A semiconductor device is generally configured to include a parasitic diode forward biased with respect to a reverse-polarity power supply voltage. Thus, if a reverse-polarity power supply voltage is applied to a semiconductor device not taking the application of a reverse-polarity power supply voltage into consideration, an excessive forward current may flow through the parasitic diode, and the elements constituting the semiconductor device may be damaged. From the perspective of preventing the damages to elements caused by such application of reverse-polarity power supply voltage, a technology for protecting an integrated circuit has been disclosed (for example, refer to Japanese Patent Application Laid-open No. H10-289956).

A protection circuit to which the technology disclosed in Japanese Patent Application Laid-open No. H10-289956 is applied has an NPN bipolar transistor containing a base, a collector, and an emitter. The base is connected with a VCC terminal that supplies a power supply voltage VCC (≠0V) via a resistor. The collector is connected with an internal circuit to be protected (hereinafter referred to as “protection object” or “protected circuit”). The emitter is connected to a GND terminal that supplies a power supply voltage of 0V.

In the state where the reverse-polarity power supply voltage is not applied, that is, in the steady state where the power supply voltage VCC is a positive voltage (VCC>0), if the power supply voltage VCC is sufficiently higher than the forward voltage Vf of the base-emitter diode of the NPN bipolar transistor, the current driving force increases and the collector-emitter voltage can be considered as being substantially 0V. Thus, in the steady state, the internal circuit can be considered as being directly connected to the GND terminal.

On the other hand, in the state where the reverse-polarity power supply voltage is applied, that is, in a power supply reverse connection state where the power supply voltage VCC is a negative voltage (VCC<0), the base voltage follows the power supply voltage VCC and the base current stops flowing. As a result, the NPN bipolar transistor in the protection circuit enters a cut-off state, and the collector current is cut off. By cutting off the collector current, it is possible to cut off the excessive forward current passing through the parasitic diode that serves as a reason of damages to the elements if the internal circuit is directly connected with the GND terminal. Consequently, the protection object can be protected from damages to elements caused by the application of reverse-polarity power supply voltage.

However, in the case of the conventional protection circuit to which the technology disclosed in Japanese Patent Application Laid-open No. H10-289956 is applied and a semiconductor device including the same, in the cut-off state of the NPN bipolar transistor provided in a protection circuit, the internal circuit becomes floating. The internal circuit being floating leaves room for improvement and may cause undesirable effects. More specifically, with the internal circuit becoming floating, the possibility of electrostatic breakdown due to charge accumulation or discharge in the protection object or the possibility of malfunction due to electromagnetic noise interference increases.

Meanwhile, if a base current is arranged to flow in the NPN bipolar transistor of the protection circuit, it is possible to prevent the internal circuit from becoming floating by keeping the NPN bipolar transistor from entering the cut-off state. However, arranging the base current to flow to the NPN bipolar transistor is undesirable as such arrangement becomes an inhibiting factor against current consumption reduction.

The present invention provides a protection circuit and a semiconductor device capable of preventing the internal circuit from becoming floating while keeping current consumption low.

### SUMMARY

A protection circuit according to an embodiment of the invention includes: a protection transistor, including a first end, a second end, and a control end, the first end being connected with a first end of a current path formed by a parasitic diode of a semiconductor element comprised in an internal circuit, and the second end being connected with a first power supply terminal; and a current limiting circuit, connected in parallel with the protection transistor.

### BRIEF DESCRIPTION OF THE DRAWINGS

FIG. 1 is a circuit diagram illustrating a configuration example (first configuration example) of a protection circuit and a semiconductor device according to a first embodiment of the present invention.

FIG. 2A is a circuit diagram illustrating a first configuration example illustrating a load including a constant current source in a step-down circuit included in the semiconductor device according to the first embodiment, FIG. 2B is a circuit diagram illustrating a first configuration example of the constant current source as the load, and FIG. 2C is a circuit diagram illustrating a second configuration example of the constant current source as the load.

FIG. 3 is a circuit diagram illustrating a configuration example (second configuration example) of the protection circuit and the semiconductor device according to the first embodiment.

FIG. 4A, FIG. 4B, and FIG. 4C are circuit diagrams illustrating a second configuration example, a third configuration example, and a fourth configuration example, respectively, of the load of the step-down circuit in the semiconductor device according to the first embodiment.

FIG. 5 is a circuit diagram illustrating a modified example (third configuration example) of a protection circuit and a semiconductor device according to the second embodiment.

FIG. 6 is a circuit diagram illustrating a modified example (fourth configuration example) of the protection circuit and the semiconductor device according to the second embodiment.

FIG. 7A, FIG. 7B, and FIG. 7C are circuit diagrams illustrating a first configuration example, a second configuration example, and a third configuration example, respectively, of a current/voltage conversion circuit included in the step-down circuit of the semiconductor device according to the second embodiment.

FIG. 8A and FIG. 8B are circuit diagrams illustrating a first configuration example and a second configuration example, respectively, of a constant current source included in the step-down circuit of the semiconductor device according to the second embodiment.

FIG. 9 is a circuit diagram illustrating a portion of a modification example (second configuration example) of the step-down circuit in the protection circuit according to the second embodiment.

### DESCRIPTION OF THE EMBODIMENTS

According to the present invention, the internal circuit can be prevented from becoming floating while current consumption is kept low.

The following describes the protection circuit and the semiconductor device according to embodiments of the present invention based on the drawings.

### First Embodiment

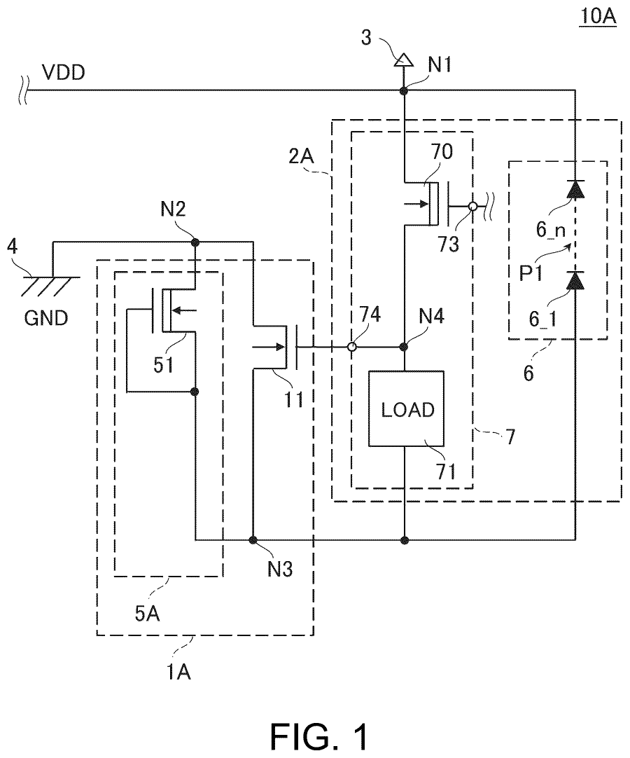

FIG. 1 is a circuit diagram of a protection circuit 1A as an example of a protection circuit according to a first embodiment and a semiconductor device 10A as an example of a semiconductor device according to the first embodiment.

The semiconductor device 10A includes a protection circuit 1A and a protected circuit 2A as a protection object of the protection circuit 1A. The protection circuit 1A and the protected circuit 2A are configured as semiconductor integrated circuits. The semiconductor device 10A includes a first end connected to a VDD terminal 3 that supplies a voltage VDD as an example of a power supply voltage, and a second end connected to a GND terminal 4, which is a ground terminal that supplies a ground voltage GND as an example of a power supply voltage different from the voltage VDD. Here, the connection point between the first end of the semiconductor device 10A and the VDD terminal 3 is referred to as a node N1, and the connection point between the second end of the semiconductor device 10A and the GND terminal 4 is referred to as a node N2.

The protected circuit 2A includes a first end corresponding to the first end of the semiconductor device 10A and connected to the node N1, a second end that is connected to the GND terminal 4 if there is no protection circuit 1A, and an output end that supplies a gate voltage Vg to the protection circuit 1A. The protection circuit 1A includes a first end connected to the second end of the protected circuit 2A, a second end connected to the GND terminal 4, and an input end that receives the supply of the gate voltage Vg from the protected circuit 2A. Here, the connection point between the protection circuit 1A (first end) and the protected circuit 2A (second end) is referred to as a node N3.

The protection circuit 1A includes an NMOS transistor 11, which is as an example of an N-type field-effect transistor (FET), and a current limiting circuit 5A connected in parallel with the NMOS transistor 11 as a protection transistor.

The NMOS transistor 11 includes a source as the first end, a drain as the second end, and a gate as the input end. The source of the NMOS transistor 11 corresponds to the first end of the protection circuit 1A and is connected to the second end of the protected circuit 2A. The drain of the NMOS transistor 11 corresponds to the second end of the protection circuit 1A and is connected to the GND terminal 4. The gate of the NMOS transistor 11 is connected to the output end of the protected circuit 2A.

The current limiting circuit 5A includes a depletion-type NMOS transistor 51 in which the gate and the source are connected, for example. In the depletion-type NMOS transistor 51, the drain is connected to the drain of the NMOS transistor 11. The source is connected to the source of the NMOS transistor 11 and the gate of the depletion-type NMOS transistor 51. The gate is connected to the source of the NMOS transistor 11. In other words, the depletion-type NMOS transistor 51 includes a drain as a first end connected to the drain of the NMOS transistor 11, a source as a second end connected to the source of the NMOS transistor 11, and a gate as a control end connected to the source of its own (the depletion-type NMOS transistor 51).

The protected circuit 2A includes an internal circuit 6 that applies a semiconductor element such as an FET, and a source follower 7 as a step-down circuit connected in parallel with the internal circuit 6.

Since parasitic diodes are included in semiconductor elements, in the internal circuit 6 to which the semiconductor elements are applied, a current path P1 is formed by one parasitic diode 6_1 or multiple n (where n is an integer of 2 or more) parasitic diodes 6_1 to 6_n and conductibly connects the node N3 and the node N1. In other words, the two ends of the current path P1 correspond to the two ends of the internal circuit 6. Here, in the two ends of the current path P1 and the internal circuit 6, the end connected to the node N1 is referred to as the first end, and the end connected to the node N3 is referred to as the second end.

The source follower 7 includes a depletion-type NMOS transistor 70 and a load 71, a control terminal 73, and an output terminal 74. The depletion-type NMOS transistor 70 and the load 71 are connected in series between the node N1 and the node N3.

The depletion-type NMOS transistor 70 as the step-down transistor includes a drain as the first end, a source as the second end, and a gate as the control end. The load 71 includes a first end connected to the second end of the current path P1, i.e., the node N3, and a second end connected to the source of the depletion-type NMOS transistor 70. Here, the connection point between the depletion-type NMOS transistor 70 (source) and the load 71 (second end) is referred to as a node N4.

In the depletion-type NMOS transistor 70, the drain is connected to the first end of the current path P1, i.e., the node N1. The source is connected to the second end of the load 71 and the output terminal 74. The gate is connected to the control terminal 73.

The control terminal 73 is connected, external to the source follower 7, to an arbitrary node capable of supplying a predetermined bias voltage Vbias, such as a node within the internal circuit 6. In the case where the control terminal 73 is connected to a node within the internal circuit 6, it is preferable that the bias voltage Vbias can be supplied without adding a new circuit. The output terminal 74 is connected, external to the source follower 7, to the gate of the NMOS transistor 11 corresponding to the input end of the protection circuit 1A.

Next, a constant current source 711, which is the first configuration example of the load 71, will be described.

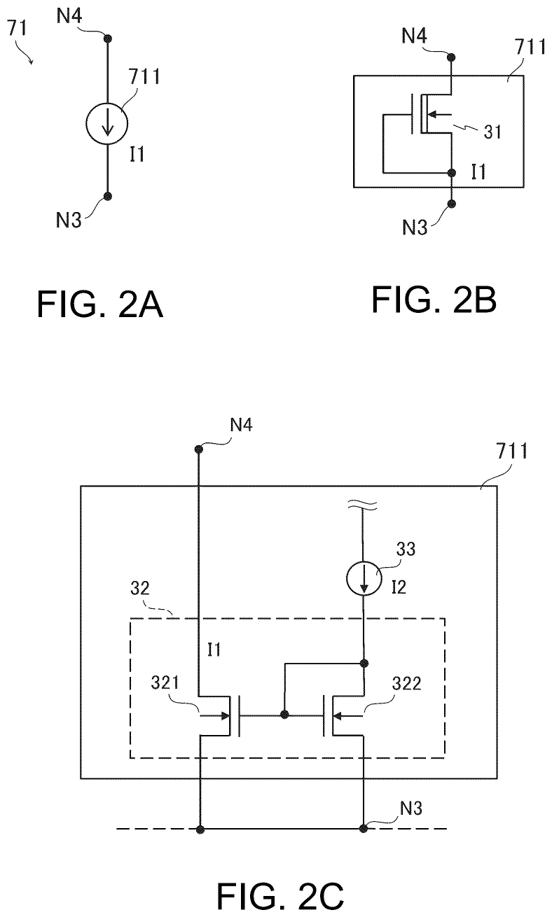

FIG. 2A is a circuit diagram illustrating the first configuration example of the load 71 including the constant current source 711. In addition, FIG. 2B is a circuit diagram illustrating the first configuration example of the constant current source 711, and FIG. 2C is a circuit diagram illustrating the second configuration example of the constant current source 711.

The constant current source 711 includes a first end connected to the node N4 and a second end connected to the node N3, and is configured to be able to supply a constant current I1 (see FIG. 2A). The constant current source 711 includes, for example, a depletion-type NMOS transistor 31 as a depletion-type FET in which the source and the gate are connected, and is configured to conduct a constant current I1 to the drain of the depletion-type NMOS transistor 31 (see FIG. 2B).

The constant current source 711 may also be configured to include a current mirror circuit 32 formed by connecting two NMOS transistors 321, 322, and a constant current source 33 that conducts a constant current I2 to the drain of the NMOS transistor 322. The current mirror circuit 32 is configured by connecting the gate of the NMOS transistor 322 to the drain of its own and the gate of the NMOS transistor 321. In the constant current source 711 having the current mirror circuit 32 and the constant current source 33, a constant current I1 (=m1×I2), which is a copy of the constant current I2 flowing to the drain of the NMOS transistor 322 at a predetermined mirror ratio m1 (m1 is an arbitrary positive number), can be conducted to the drain of the NMOS transistor 321.

Next, the circuit operation of the protection circuit 1A and the semiconductor device 10A will be explained sequentially by dividing the operation into: (1) a state (hereinafter referred to as “steady state”) where the power supply is correctly connected and the voltage VDD (>0V), which is a positive power supply voltage, is supplied from the VDD terminal 3; (2) a state where the power supply is reverse-connected and the voltage VDD (<0V), which a negative power supply voltage, is supplied from the VDD terminal 3 (hereinafter referred to as “reverse connection state”); (3) a state where the internal circuit 6 is in standby (hereinafter simply referred to as “standby state”), and (4) a state where the voltage VDD is not supplied from the VDD terminal 3 (hereinafter referred to as “VDD terminal open state”).

### (1) Steady State

The current flowing through the internal circuit 6 flows in a direction from the VDD terminal 3 to the GND terminal 4, that is, from the node N1 towards the node N3. In the case of controlling the NMOS transistor 11 by supplying a gate voltage Vg from the source follower 7, the bias voltage Vbias, which is the gate voltage of the depletion-type NMOS transistor 70, is set so that the gate voltage Vg of the NMOS transistor 11 exceeds a threshold voltage Vth thereof. By applying the bias voltage Vbias so set to the gate of the depletion-type NMOS transistor 70, the NMOS transistor 11 is turned on and conducts a current in a direction from the source (the node N3) of the NMOS transistor 11 to the drain (the node N2).

The gate voltage Vg can be approximated by the following equation (1) by using the bias voltage Vbias, a gate-source voltage Vgs of the depletion-type NMOS transistor 70, and a threshold voltage Vth_sf of the depletion-type NMOS transistor 70:

$$Vg = V bias - Vgs = Vbias - Vth\_sf > Vth \qquad ( 1 )$$

Here, in the case where the depletion-type NMOS transistor 70, which is a depletion-type FET having a negative threshold voltage, is used as the step-down transistor of the source follower 7, it is possible to configure the source follower 7, so that the gate voltage Vg is greater than the bias voltage Vbias, that is, so as to satisfy the following equation (2):

$$Vg ≧ Vbias \qquad ( 2 )$$

By configuring the source follower 7 to satisfy the above equation (2), it becomes easier to turn on the NMOS transistor 11.

Meanwhile, the depletion-type NMOS transistor 51 in which the gate and the source are connected (shorted) can be considered as a diode-connected FET in the steady state, so the depletion-type NMOS transistor 51 conducts a current in a direction from the source to the drain in the ON-state. Here, to operate the internal circuit 6 stably, it is preferable to operate the voltage of the node N3, which is the reference node thereof, at a voltage close to the ground voltage GND that is the voltage of the GND terminal 4. In the case where the voltage of the node N3 is set close to the ground voltage GND, both of the NMOS transistor 11 and the depletion-type NMOS transistor 51 operate in a resistance region where the drain-source voltage is close to 0V. Thus, the current flowing from the node N1 connected to the VDD terminal 3 to the node N3 flows to the GND terminal 4 through the respective ON-resistances of the NMOS transistor 11 and the depletion-type NMOS transistor 51.

Here, when the voltage of the node N3, the ON-resistance of the NMOS transistor 11, the ON-resistance of the depletion-type NMOS transistor 51, the composite resistance in which the ON-resistance of the NMOS transistor 11 and the ON-resistance of the depletion-type NMOS transistor 51 are connected in parallel and the current flowing from the node N3 to the node N4 are respectively denoted as a voltage VN3, a resistance Ron_prt, a resistance Ron_dep, a resistance Ron(=Ron_prt/Ron_dep), and a current Iope_gnd, respectively, the equation (3) can be represented as follows.

$$VN 3 = ( Ron\_prt // Ron\_dep ) \times Iope\_gnd = Ron \times Iope\_gnd \qquad ( 3 )$$

From the equation (3), by designing the composite resistance value Ron to be sufficiently small, such as by increasing the aspect ratios of the NMOS transistor 11 and the depletion-type NMOS transistor 51, or by setting the gate voltage Vg supplied to the gate of the NMOS transistor 11 to be high, the internal circuit 6 can be brought close to a state of being connected to the GND terminal 4, that is, a grounded state. By bringing the internal circuit 6 close to the grounded state, it is possible to prevent the internal circuit 6 from floating.

### (2) Reverse Connection State

In response to a negative voltage being applied to the VDD terminal 3, the gate voltage Vg of the NMOS transistor 11 and the voltage VN3 of the node N3 decrease by following the voltage VDD due to the forward bias of the parasitic diodes 6_1 to 6_n in the internal circuit 6. As the gate voltage Vg of the NMOS transistor 11 and the voltage VN3 of the node N3 decrease, and the gate-source voltage Vgs11 of the NMOS transistor 11 falls below the threshold voltage Vth, the NMOS transistor 11 is turned off.

Meanwhile, the depletion-type NMOS transistor 51 in which the gate and source are connected (shorted) can be considered as a constant current source, so the depletion-type NMOS transistor 51 can limit the current flowing in a direction from the drain connected to the node N2 to the source connected to the node N3. Here, since a threshold voltage VTND of the depletion-type NMOS transistor 51 is negative (VTND<0V) and a gate-source voltage Vgs51 is 0V (Vgs51=0V), with the drain-source voltage being equal to or greater than an absolute value |VTND| of the threshold voltage, the depletion-type NMOS transistor 51 operates in a saturated region based on the equation (4), which is an equation for a transistor in general:

$$VDS ≧ VGS - VTH \qquad ( 4 )$$

VDS: drain-source voltage
VGS: gate-source voltage
VTH: threshold voltage

Here, when the current flowing in a direction from the drain of the depletion-type NMOS transistor 51 to the source is defined as a reverse current Irev, and a transconductance coefficient Kdep of the depletion-type NMOS transistor 51 is defined as a constant, the reverse current Irev is the drain current of the depletion-type NMOS transistor 51, so the equation (5) can be represented as follows:

$$Irev = Kdep \times \vert VTND \vert 2 \qquad ( 5 )$$

The reverse current Irev may be a reverse current flowing to the VDD terminal 3 through the protected circuit 2A (more specifically, the internal circuit 6 or the source follower 7), so it is generally not desirable. However, by reducing the aspect ratio of the depletion-type NMOS transistor 51, etc., the transconductance coefficient Kdep can be reduced. By setting the transconductance coefficient Kdep to a small value, the depletion-type NMOS transistor 51 able to limit the reverse current Irev to an acceptable current value can be arranged.

### (3) Standby State

In the standby state, the current flowing to the source follower 7 is cut off to reduce current consumption. In the state where the current flowing to the source follower 7 is cut off, the gate voltage Vg of the NMOS transistor 11 decreases below the threshold voltage Vth of the NMOS transistor 11, and the NMOS transistor 11 is turned off. Meanwhile, the depletion-type NMOS transistor 51 in which the gate and the source are connected (shorted) can be considered as a diode-connected FET, similar to the steady state of (1), and operates in the resistance region of the resistance Ron_dep that is the ON-resistance thereof.

Here, if the current flowing through the internal circuit 6 in the standby state of (3) is defined as a standby current Istb, the voltage VN3 at the node N3 can be expressed by the following equation (6):

$$VN 3 = Ron\_dep \times Istb \qquad ( 6 )$$

From the equation (6), if the design ensures that the composite resistance value Rdep is sufficiently small, such as by increasing the aspect ratio of the depletion-type NMOS transistor 51, the internal circuit 6 can be brought close to the grounded state, that is, a state in which the internal circuit 6 is connected to the GND terminal 4, similar to (1) steady state, even in the standby state in which the current consumption is suppressed. By bringing the internal circuit 6 close to the grounded state, it is possible to prevent the internal circuit 6 from floating.

### (4) VDD Terminal Open State

In the VDD terminal open state, the NMOS transistor 11 is turned off because the voltage VDD is not supplied from the VDD terminal 3 to the node N1. Meanwhile, the depletion-type NMOS transistor 51 in which the gate and the source are connected (shorted) can be considered as a diode-connected FET and operates in the resistance region of the on-resistance Ron_dep, like the steady state of (1) and the standby state of (3). Thus, similar to the steady state (1) and the standby state of (3), the internal circuit 6 can be brought close to the grounded state. By bringing the internal circuit 6 close to the grounded state, it is possible to prevent the internal circuit 6 from floating.

Here, an example of the design procedure is described as follows for being able to bring the internal circuit 6 close to the grounded state in the steady state of (1), the standby state of (3), and the VDD terminal open state of (4), while limiting the reverse current Irev to an acceptable current value in the reverse connection state of (2).

First, by using the equations (5) and (6), the aspect ratio of the depletion-type NMOS transistor 51 is determined, so that the reverse current Irev and the voltage VN3 (=Ron_dep×Istb) at the node N3 in the standby state achieve the desired values. At the time of determining the aspect ratio of the depletion-type NMOS transistor 51, if a small reverse current Irev is desired, the aspect ratio of the depletion-type NMOS transistor 51 is set to be small. After determining the aspect ratio of the depletion-type NMOS transistor 51, by using the equation (3), the aspect ratio of the NMOS transistor 11 and the gate voltage Vg thereof are determined, so that the voltage VN3 at the node N3 in the steady state of (1) becomes the desired value.

With such design, it is possible to configure the protection circuit and the semiconductor device according to the embodiment so as to be able to bring the internal circuit 6 close to the grounded state in the steady state of (1), the standby state of (3), and the VDD terminal open state of (4), while being able to limit the reverse current Irev to an acceptable current value in the reverse connection state of (2).

As described above, according to the protection circuit 1A and the semiconductor device 10A, with a configuration in which the protection circuit 1A includes the current limiting circuit 5A connected in parallel with the NMOS transistor 11, even if the NMOS transistor 11 is in the OFF state, a current path between the internal circuit 6 and the GND terminal 4 can be secured. Thus, a current path between the internal circuit 6 and the GND terminal 4 can be secured, and floating of the internal circuit 6 can be prevented.

With the configuration in which the protection circuit 1A includes the current limiting circuit 5A connected in parallel with the NMOS transistor 11, the protection circuit 1A and the semiconductor device 10A can bring the internal circuit 6 close to the grounded state in the steady state of (1), the standby state of (3), and the VDD terminal open state of (4), while being able to limit the reverse current Irev to an acceptable current value in the reverse connection state of (2).

The protection circuit and the semiconductor device according to the first embodiment are not limited to the protection circuit 1A and semiconductor device 10A described above. In the following, other configuration examples (modification examples) of the protection circuit 1A and semiconductor device 10A will be described.

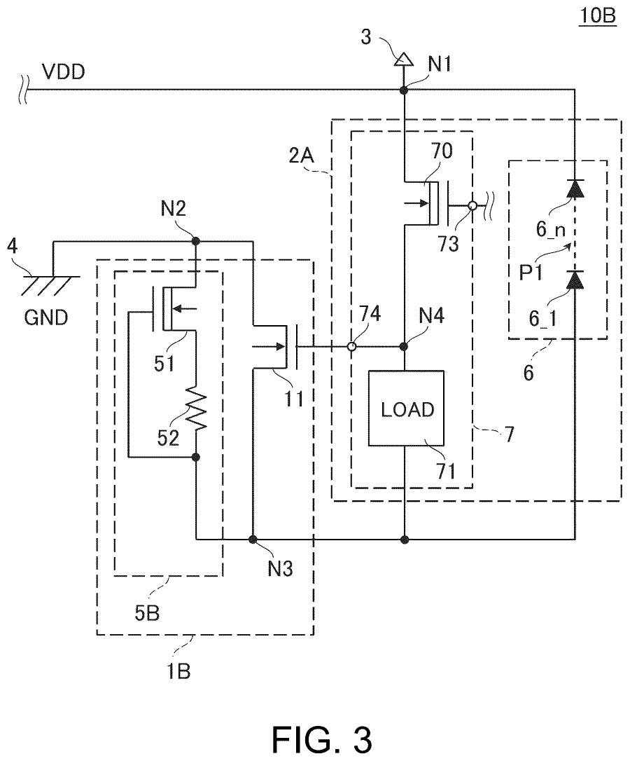

FIG. 3 is a circuit diagram illustrating a protection circuit 1B and a semiconductor device 10B, which is a modified example (second configuration example) of the protection circuit and the semiconductor device according to the first embodiment.

The semiconductor device 10B differs from the semiconductor device 10A in that the semiconductor device 10B includes a protection circuit 1B instead of the protection circuit 1A, but does not substantially differ in other aspects. The protection circuit 1B differs from the protection circuit 1A in that the protection circuit 1B includes a current limiting circuit 5B instead of the current limiting circuit 5A, but does not substantially differ in other aspects. The current limiting circuit 5B differs from the current limiting circuit 5A in that the current limiting circuit 5B further includes a resistor 52 connected between the source of the depletion-type NMOS transistor 51 and the node N3.

In the current limiting circuit 5B, the depletion-type NMOS transistor 51 includes a drain connected to the drain of the NMOS transistor 11, a source as a second end, and a gate as a control end. The resistor 52 includes a first end connected to the source of the depletion-type NMOS transistor 51, and a second end connected to the source of the NMOS transistor 11 and the gate of the depletion-type NMOS transistor 51. In other words, the resistor 52 conductibly connects the source of the depletion-type NMOS transistor 51 and the source of the NMOS transistor 11 connected to the gate of the depletion-type NMOS transistor 51.

According to the protection circuit 1B and the semiconductor device 10B so configured, although the resistance values between the two ends of the current limiting circuit 5B, that is, between the node N2 and the node N3, differ from the resistance values between the two ends of the current limiting circuit 5A, the protection circuit 1B and semiconductor device 10B operate similarly to the protection circuit 1A and semiconductor device 10A.

In the protection circuit 1B and the semiconductor device 10B, since the resistor 52 and the depletion-type NMOS transistor 51 are in serial arrangement, the equations (3) and (6) become equations where “Ron_dep” in the equations (3) and (6) is replaced with “Ron_dep+R52”. Here, “R52” is the resistance value of the resistor 52. Moreover, in the reverse connection state of (2), since the voltage drop of the resistor 52 becomes substantially the absolute value |VTND| of the threshold voltage of the depletion-type NMOS transistor 51, the reverse current Irev becomes a value obtained by dividing the absolute value |VTND| of the threshold voltage of the depletion-type NMOS transistor 51, which corresponds to the voltage drop of the resistor 52, by the resistance value “R52”, as represented in the equation (7) as follows.

$$Irev = \vert VTND \vert / R 52 \qquad ( 7 )$$

According to the protection circuit 1B and the semiconductor device 10B, with a configuration in which the protection circuit 1B includes the current limiting circuit 5B connected in parallel with the NMOS transistor 11, even if the NMOS transistor 11 is in the OFF state, a current path between the internal circuit 6 and the GND terminal 4 can be secured. Therefore, a current path between the internal circuit 6 and the GND terminal 4 can be secured, and floating of the internal circuit 6 can be prevented.

With the configuration in which the protection circuit 1B includes the current limiting circuit 5B connected in parallel with the NMOS transistor 11, the protection circuit 1B and the semiconductor device 10B can bring the internal circuit 6 close to the grounded state in the steady state of (1), the standby state of (3), and the VDD terminal open state of (4), while being able to limit the reverse current Irev to an acceptable current value in the reverse connection state of (2).

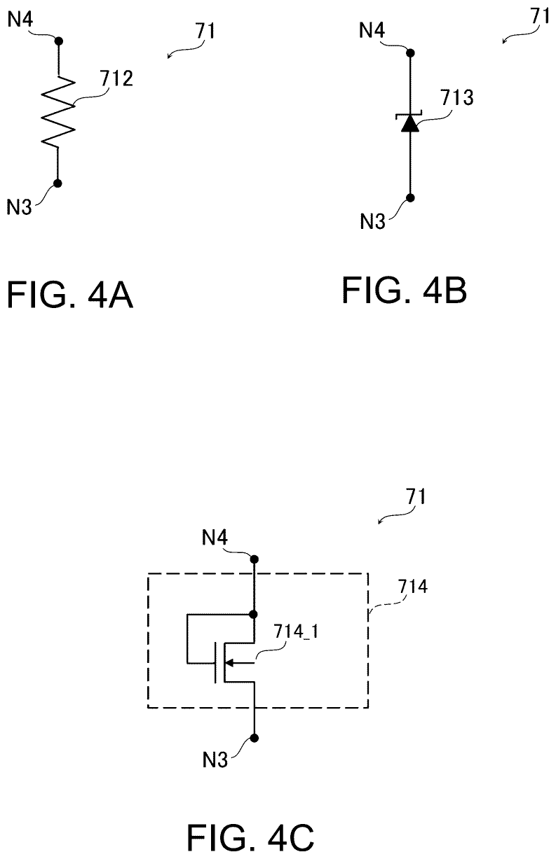

In the first embodiment, up to this point, an example (first configuration example: see FIG. 2A to FIG. 2C) of the load 71, which is the constant current source 711, has been described, but the load 71 is not limited to the case of the constant current source 711. For example, the load 71 may be configured as illustrated in FIGS. 4A, 4B, and 4C to be described later.

FIGS. 4A, 4B, and 4C are circuit diagrams illustrating a resistor 712 as a second configuration example of the load 71, a Zener diode 713 as a third configuration example of the load 71, and a transistor circuit 714 as a fourth configuration example of the load 71, respectively.

In the embodiment, the load 71 may be, for example, the resistor 712 (the second configuration example, see FIG. 4A), or the Zener diode 713 (the third configuration example, see FIG. 4B), or the transistor circuit 714 including at least one diode-connected MOS transistor 714_1 (the fourth configuration example, see FIG. 4C). The transistor circuit 714 is not limited to the case including one diode-connected MOS transistor 714_1, but may be configured with multiple diode-connected MOS transistors, including the MOS transistor 714_1, connected in series.

### Second Embodiment

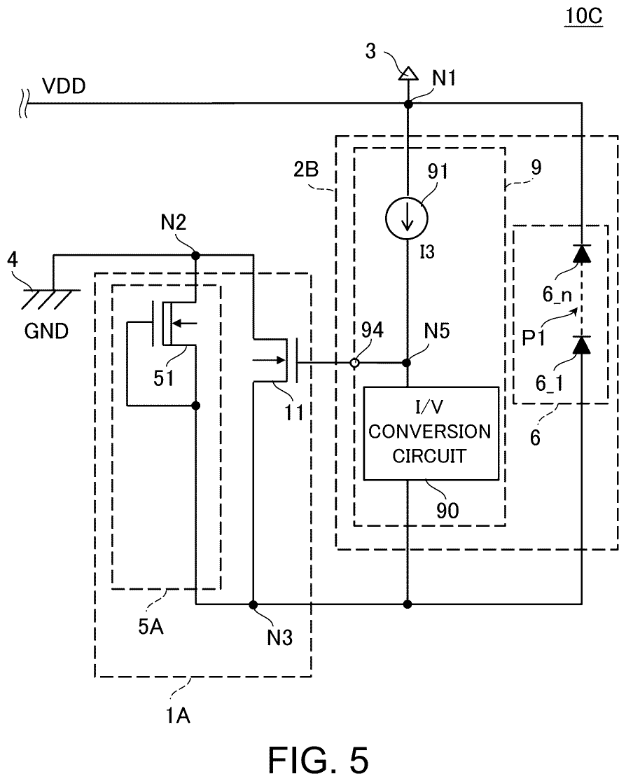

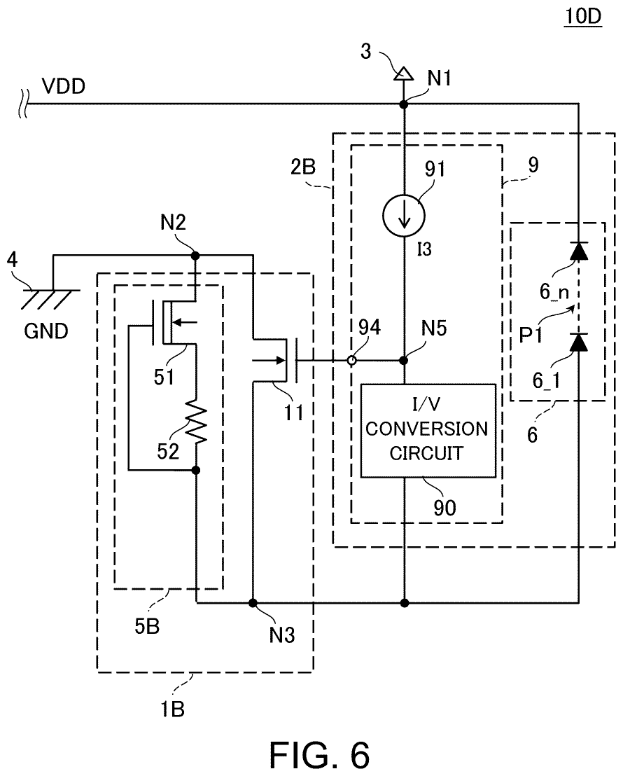

FIG. 5 and FIG. 6 illustrate an example of a semiconductor device according to a second embodiment, and are circuit diagrams illustrating a semiconductor device 10C including the protection circuit 1A and a semiconductor device 10D including the protection circuit 1B, respectively.

The semiconductor devices 10C and 10D differ from the semiconductor devices 10A (see FIG. 1) and 10B (see FIG. 3) in that the semiconductor devices 10C and 10D include a protected circuit 2B instead of the protected circuit 2A (see FIG. 3, 4) included in semiconductor devices 10A and 10B. More specifically, the semiconductor devices 10C and 10D include a step-down circuit 9 instead of the source follower 7 as the step-down circuit, but do not differ substantially in other aspects. Thus, in the description of the embodiment, the points that differ from the aforementioned embodiment is described, whereas the repeated description is omitted. The difference between the semiconductor device 10C and the semiconductor device 10D is substantially the same as the difference between the semiconductor device 10A and the semiconductor device 10B. Thus, in the embodiment, the semiconductor device 10C is described. For the semiconductor device 10D, the protection circuit 1A, the current limiting circuit 5A, and the semiconductor device 10C are respectively replaced with the protection circuit 1B, the current limiting circuit 5B, and the semiconductor device 10D and therefore omitted.

The semiconductor device 10C includes the protection circuit 1A and the protected circuit 2B, as a protection object of the protection circuit 1A. The protection circuit 1A and the protected circuit 2B are configured as semiconductor integrated circuits.

The protected circuit 2B includes the internal circuit 6 and the step-down circuit 9 connected in parallel with the internal circuit 6. In addition, the protected circuit 2B includes a first end corresponding to the first end of the semiconductor device 10A and connected to the node N1, a second end that is connected to the GND terminal 4 if there is no protection circuit 1A, and an output end that supplies the gate voltage Vg to the protection circuit 1A.

The step-down circuit 9 according to the first configuration example includes a current-voltage conversion circuit (hereinafter referred to as “I/V conversion circuit”) 90, a constant current source 91, and an output terminal 94. Here, the connection point of the constant current source 91 and the I/V conversion circuit 90 is referred to as a node N5.

The constant current source 91 includes a first end connected to the node N1 and a second end connected to the node N5, and is configured to be able to supply a constant current I3. The I/V conversion circuit 90 includes a first end connected to the node N3 and a second end connected to the node N5, and is configured to be able of convert the constant current I3 supplied from the constant current source 91 into the gate voltage Vg and output to the node N5. The output terminal 94 is connected to the node N5 in the step-down circuit 9. Meanwhile, outside the step-down circuit 9, the output terminal 94 is connected to the gate of the NMOS transistor 11.

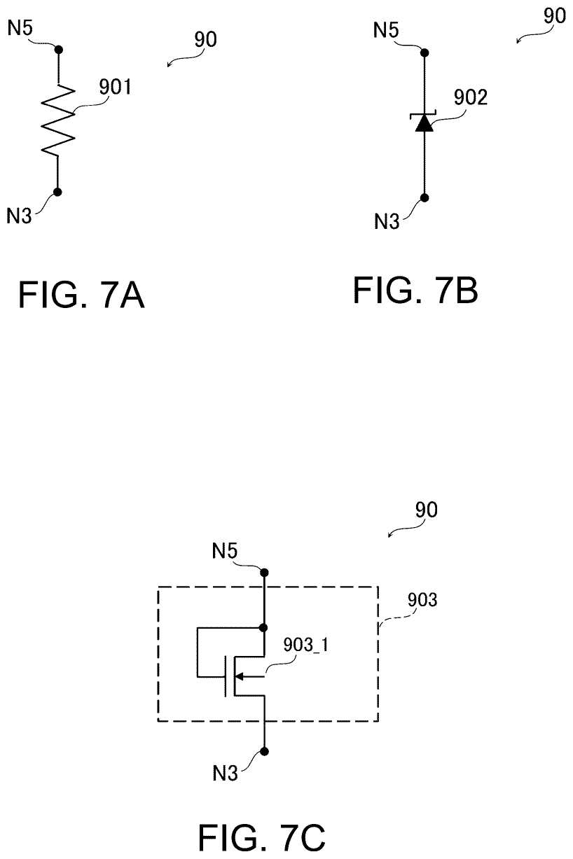

Next, a configuration example of the I/V conversion circuit 90 will be described. FIG. 7A, FIG. 7B, and FIG. 7C are circuit diagrams illustrating the first configuration example having a resistor 901, the second configuration example having a Zener diode 902, and the third configuration example having a transistor circuit 903, respectively, of the I/V conversion circuit 90.

The I/V conversion circuit 90 is configured, for example, by the resistor 901 (the first configuration example, see FIG. 7A), the Zener diode 902 (the second configuration example, see FIG. 7B), or the transistor circuit 903 including at least one diode-connected MOS transistor 903_1 (fourth configuration example, see FIG. 7C). The transistor circuit 903 is not limited to the case including one diode-connected MOS transistor 903_1, but may also be configured with multiple diode-connected MOS transistors connected in series, including the MOS transistor 903_1, connected in series.

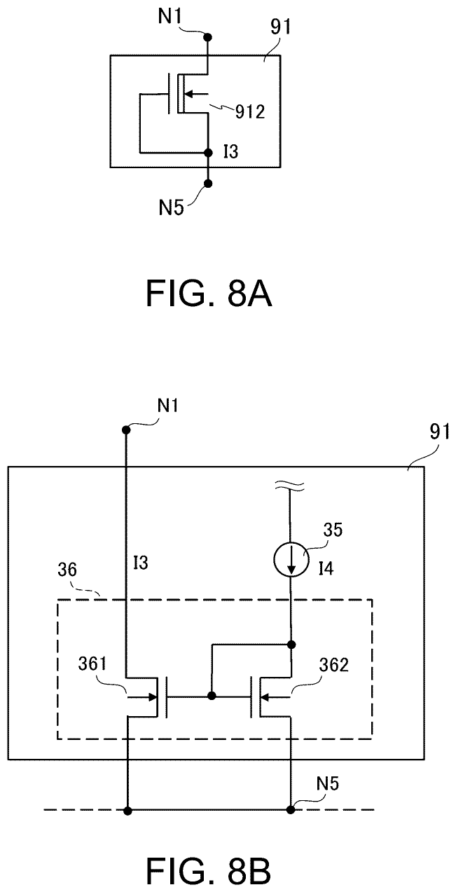

Next, a configuration example of the constant current source 91 will be described. FIG. 8A and FIG. 8B are circuit diagrams illustrating the first configuration example having a depletion-type NMOS transistor 912 in which the gate and the source are connected, and the second configuration example having a constant current source 35 and a current mirror circuit 36, respectively, of the constant current source 91.

The constant current source 91 includes, for example, the depletion-type NMOS transistor 912 as a depletion-type FET in which the source and the gate are connected, and is configured to conduct the constant current I3 through the drain of the depletion-type NMOS transistor 912 (see FIG. 8A).

The constant current source 91 is also configured to include a current mirror circuit 36 formed by connecting two NMOS transistors 361, 362, and a constant current source 35 that conducts a constant current I4 through the drain of the NMOS transistor 362. The current mirror circuit 36 is configured by connecting the gate of the NMOS transistor 362 to the drain of its own and the gate of the NMOS transistor 361. In the constant current source 91 having the current mirror circuit 36 and the constant current source 35, the constant current I3 (=m2×I4), which is a copy of the constant current I4 flowing through the drain of the NMOS transistor 362 at a predetermined mirror ratio m2 (m2 is an arbitrary positive number), can be conducted through the drain of the NMOS transistor 361.

Next, the circuit operation of the protection circuit 1A and the semiconductor device 10C, divided into the steady state of (1), the reverse connection state of (2), the standby state (3), and the VDD terminal open state of (4), will be described in order. At the time of describing the circuit operation of the semiconductor device 10C, the description that repeats those of the semiconductor device 10A will be appropriately simplified or omitted.

### (1) Steady State

The current flowing through the internal circuit 6 flows from the node N1 towards the node N3. The constant current I3 of the constant current source 91 is set so that the gate voltage Vg of the NMOS transistor 11 from the step-down circuit 9 exceeds the threshold voltage Vth. By supplying the constant current I3 so set to the I/V conversion circuit 90, it is possible to generate and supply the gate voltage Vg that easily turns on the NMOS transistor 11 to the gate of the NMOS transistor 11. Other aspects are similar to the circuit operation of the protection circuit 1A and the semiconductor device 10A.

### (2) Reverse Connection State

The reverse current Irev in the protection circuit 1A and the semiconductor device 10C differs from the reverse current Irev in the protection circuit 1A and the semiconductor device 10A in that the reverse current Irev in the protection circuit 1A and the semiconductor device 10C becomes a current flowing to the VDD terminal 3 through the protected circuit 2B (more specifically, the internal circuit 6 or the step-down circuit 9). However, the circuit operation of the protection circuit 1A and the semiconductor device 10C is similar to that of the protection circuit 1A and the semiconductor device 10A.

### (3) Standby State

The semiconductor device 10C includes a switch (not illustrated) to cut off the current flowing to the step-down circuit 9 in order to transition to the standby state. In the standby state, to reduce current consumption, the current flowing to the step-down circuit 9 is cut off by turning off the switch. In the state where the current flowing to the step-down circuit 9 is cut off, the gate voltage Vg of the NMOS transistor 11 decreases below the threshold voltage Vth of the NMOS transistor 11, and the NMOS transistor 11 is turned off. Other aspects are similar to the circuit operation of the protection circuit 1A and the semiconductor device 10A.

### (4) VDD Terminal Open State

In the VDD terminal open state, the circuit operation of the protection circuit 1A and the semiconductor device 10C is similar to that of the protection circuit 1A and the semiconductor device 10A.

As described above, the protection circuit 1A and the semiconductor device 10C provide effects similar to those of the protection circuit 1A and the semiconductor device 10A. In other words, the protection circuit 1A and the semiconductor device 10C can secure a current path between the internal circuit 6 and the GND terminal 4, thereby preventing the internal circuit 6 from floating. Additionally, in the steady state of (1), the standby state of (3), and the VDD terminal open state of (4), the internal circuit 6 can be brought close to the grounded state, while in the reverse connection state of (2), the reverse current Irev can be limited to an acceptable current value.

Moreover, the protection circuit 1B and the semiconductor device 10D provide similar effects to those of the protection circuit 1B and the semiconductor device 10B. In other words, the protection circuit 1B and the semiconductor device 10D can secure a current path between the internal circuit 6 and the GND terminal 4, thereby preventing the internal circuit 6 from floating. Additionally, in the steady state of (1), the standby state of (3), and the VDD terminal open state of (4), the internal circuit 6 can be brought close to the grounded state, while in the reverse connection state of (2), the reverse current Irev can be limited to an acceptable current value.

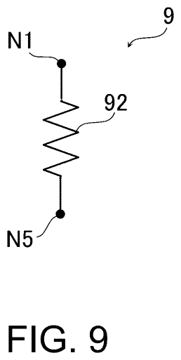

In the second embodiment, while an example of the step-down circuit 9 having the constant current source 91 and the I/V conversion circuit 90 has been described thus far, the step-down circuit 9 is not limited to this example. For instance, as illustrated in FIG. 9 to be described later, the step-down circuit 9 may be configured differently.

FIG. 9 is a circuit diagram illustrating a resistor 92, which is a portion of the second configuration example of the step-down circuit 9 having the resistor 92 and the I/V conversion circuit 90.

The step-down circuit 9 according to the second configuration example differs from the step-down circuit 9 of the first configuration example in that the step-down circuit 9 according to the second configuration example has the resistor 92 instead of the constant current source 91, but does not substantially differ in other aspects. The step-down circuit 9 according to the second configuration example generates the gate voltage Vg from the output terminal 94, similar to the step-down circuit 9 of the first configuration example. The gate voltage Vg is supplied to the protection circuit 1A. The operation of the protection circuit 1A is as described above.

It should be noted that the present invention is not limited to the embodiments described above, and at the implementation stage, it can be implemented in various forms other than the examples described above. Within the scope of the invention, various omissions, additions, substitutions, or modifications can be made. For example, while the protection circuits 1A and 1B described above are examples that do not include the source follower 7 or the step-down circuit 9, the protection circuits 1A and 1B may be configured to further include the source follower 7 or the step-down circuit 9.

In the embodiments described above, the depletion-type NMOS transistor 70 is described as an example of the step-down transistor, but the invention is not limited thereto. The step-down transistor may also be an enhancement-type transistor.

The semiconductor device according to the embodiment is described with an example where the voltage VDD is a positive voltage in the steady state. However, the protection circuit and semiconductor device according to the embodiment may be also configured by reversing the polarity (P-type and N-type) of elements having polarity, such as the depletion-type NMOS transistor 11, and the polarity (positive and negative) of the power supply voltage.

The MOS transistors in the protection circuit and semiconductor device according to the embodiment are examples of field-effect transistors (FETs), and any type of FET can be used. In other words, in addition to MOSFETs, other field-effect transistors such as junction FETs (JFETs) or metal-insulator-semiconductor FETs (MISFETs) may be chosen as appropriate.

The embodiments and the modifications thereof are included in the scope and gist of the present invention, as well as within the scope of the invention described in the claims and its equivalents.

What is claimed is:

1. A protection circuit, comprising:
a protection transistor, comprising a first end, a second end, and a control end, the first end being connected with a first end of a current path formed by a parasitic diode of a semiconductor element comprised in an internal circuit, and the second end being connected with a first power supply terminal; and
a current limiting circuit, connected in parallel with the protection transistor.

2. The protection circuit as claimed in claim 1, further comprising: a step-down circuit connected in parallel with the internal circuit,
wherein the step-down circuit comprises:
a load, having a first end and a second end, the first end being connected with the first end of the current path;
a step-down transistor, having a first end, a second end, and a control end, the first end being connected with an other end of the current path, and the second end being connected with the second end of the load;
a control terminal, connected with the control end of the step-down transistor; and
an output terminal, connected with the second end of the load and the second end of the step-down transistor.

3. The protection circuit as claimed in claim 2, wherein the control terminal of the step-down circuit is connected with an arbitrary node comprised in the internal circuit.

4. The protection circuit as claimed in claim 1, further comprising: a step-down circuit connected in parallel with the internal circuit,
wherein the step-down circuit comprises:
a current-voltage conversion circuit, comprising a first end and a second end, the first end being connected with the first end of the protection transistor and a second end of the internal circuit;
a constant current source, comprising a first end and a second end, the first end being connected with a first end of the internal circuit, and the second end being connected with the second end of the current-voltage conversion circuit; and
an output terminal, connected with the second end of the constant current source and the second end of the current-voltage conversion circuit.

5. The protection circuit as claimed in claim 1, further comprising: a step-down circuit connected in parallel with the internal circuit,
wherein the step-down circuit comprises:
a current-voltage conversion circuit, comprising a first end and a second end, the first end being connected with the first end of the protection transistor and a second end of the internal circuit; and
a resistor, comprising a first end and a second end, the first end being connected with a first end of the internal circuit, and the second end being connected with the second end of the current-voltage conversion circuit.

6. The protection circuit as claimed in claim 1, wherein the current limiting circuit comprises:
a depletion-type field-effect transistor having a first end, a second end, and a control end, the first end being connected with the second end of the protection transistor, the second end being connected with the first end of the protection transistor, and the control end being connected with the second end of the depletion-type field-effect transistor's own.

7. The protection circuit as claimed in claim 1, wherein the current limiting circuit comprises:
a depletion-type field-effect transistor having a first end, a second end, and a control end, the first end being connected with the second end of the protection transistor; and
a resistor, comprising a first end and a second end, the first end being connected with the second end of the depletion-type field-effect transistor, and the second end being connected with the first end of the protection transistor and the control end of the depletion-type field effect transistor.

8. A semiconductor device, comprising:
the protection circuit as claimed in claim 1; and
a protected circuit, having the internal circuit.
